(19) United States
(12) Patent Application Publication
(10) Pub. No.: US 2004/0187778 A1
(43) Pub. Date: Sep. 30, 2004

(54) Process and device for producing a layer of tantalum pentoxide on a carrier material, in particular titanium nitride, and integrated circuit incorporating a layer of tantalum pentoxide

(75) Inventors: Mickael Gros-Jean, Grenoble (FR); Nicolas Jourdan, Grenoble (FR); Jean Michailos, Meylan (FR)

Correspondence Address: FLEIT, KAIN, GIBBONS, GUTMAN, BONGINI, & BIANCO P.L., ONE BOCA COMMERCE CENTER, 551 NORTHWEST 77TH STREET, SUITE 111, BOCA RATON, FL, 33487, US

(73) Assignee: STMICROELECTRONICS S.A., MONTROUGE (FR)

(21) Appl. No.: 10/720,838

(22) Filed: Nov. 24, 2003

(30) Foreign Application Priority Data
Nov. 26, 2002 (FR) 02 14798

(51) Int. Cl. C23C 16/00

(52) U.S. Cl. 118/715; 118/725

(57) ABSTRACT

Carrier material (PL) is heated (MCH) to a heating temperature of between 200° C. and 400° C. and a gas mixture (MG) including tert-butyliminotris (diethylamino) tantalum (t-BuN=Ta(NEt₂)₃) is circulated in contact with the heated carrier material under an oxidizing atmosphere thereby forming a layer of tantalum pentoxide (Ta₂O₅) on the carrier material. The partial pressure of the tert-butyliminotris (diethylamino) tantalum is preferably greater than or equal to 25 mTorr.

### CROSS-REFERENCE TO RELATED APPLICATION

This application is based upon and claims priority from prior French Patent Application No. 02 14798, filed on Nov. 26, 2002, the entire disclosure of which is herein incorporated by reference.

### BACKGROUND OF THE INVENTION

1. Field of the Invention

The invention relates to integrated circuits and more particularly to the production of a layer of tantalum pentoxide (Ta₂O₅) on a carrier material, for example titanium nitride.

2. Description of the Related Art

The conventional tantalum precursor for the deposition of tantalum pentoxide is tantalum pentaethoxide (Ta(OEt)₅), also known to a person skilled in the art under the abbreviation TAETO. The TAETO precursor is currently used for the manufacture of capacitors for DRAMs in 0.18 micron or greater technologies. This is because such technologies are excellent at withstanding high thermal budgets occasioned in particular by the high temperature (much greater than 400° C.) for deposition of TAETO.

However, while the capacitors of DRAM cells are manufactured at the beginning of the process, metal-insulator-metal capacitors (MIM capacitors) are typically capacitors produced at the end of the process for the manufacture of the integrated circuit and, for example, after the 4-level metal. In addition, these capacitors have to be produced under a much lower thermal budget, so as not to damage the other components of the integrated circuit that have already been produced.

Likewise, much more advanced technologies, for example technologies of less than 0.1 micron, generally withstand much lower thermal budgets, typically less than or equal to 400° C.

Furthermore, the formation of tantalum pentoxide on silicon results in the formation of a layer of silicon dioxide having a low dielectric constant. This then results in a decrease in the overall capacity of the capacitor produced.

It has consequently been contemplated to form tantalum pentoxide on titanium nitride (TiN). However, if the titanium nitride is brought to an excessively high temperature during the formation of the tantalum pentoxide, which is the case with the use of a precursor such as TAETO, a reaction then occurs between the oxygen and the titanium nitride that leads to decomposition of the interface between the titanium nitride and the tantalum pentoxide.

For all these reasons, it is contemplated to use a precursor other than TAETO.

In this respect, tests have been carried out at a temperature of the order of 400° C. with, as precursor, tantalum tetraethoxide dimethylaminoethoxide, also known to a person skilled in the art under its abbreviation of TATDMAE (Ta(OEt)₄(OCH₂CH₂NMe₂).

However, in the light of some tests carried out, a tantalum pentoxide dielectric of very poor quality is obtained, indeed of an even poorer quality than that obtained with TAETO as precursor.

tert-Butyliminotris (diethylamino) tantalum (t-BuN═Ta (NEt₂)₃), also known to a person skilled in the art under its abbreviation of TBTDET, is also known as organometallic precursor.

The TBTDET precursor decomposes at a lower temperature than the TAETO precursor. For this reason, it has been used to form layers of tantalum nitride (TaN). Numerous patents have disclosed this use. Mention may be made, in this respect, of U.S. Pat. Nos. 5,668,054, 6,153,519, 6,215,189, 6,265,311, 6,268,288, 6,376,371, 6,410,432, 6,410,433, 6,413,860, 6,416,822 and 6,428,859.

Furthermore, experiments have been carried out to form tantalum pentoxide by using the organometallic precursor TBTDET as precursor. However, these experiments proved to be disappointing and unsatisfactory as the dielectric thus obtained is of poor quality. In other words, a capacitor with a dielectric formed of tantalum pentoxide currently obtained by using TBTDET as precursor would exhibit significant leakage currents, which is completely unacceptable for incorporation in an integrated circuit.

In addition, a person skilled in the art knows that the manufacture of an integrated circuit requires heat treatments, such as annealings, at various stages in the manufacturing process.

In point of fact, it proved to be the case that the tantalum pentoxide layers produced experimentally until now were thermodynamically unstable. More specifically, even if a layer produced at a given temperature exhibited an acceptable quality in terms of leakage current, the application, to such a layer incorporated in an integrated circuit, of subsequent treatments, such as heat annealing treatments, etching, and the like, resulted in the end in a layer highly degraded in terms of leakage current. Consequently, the experiments carried out until now to obtain tantalum pentoxide with TBTDET as precursor are completely incompatible with the incorporation of such a dielectric layer in an integrated circuit.

Accordingly, there exists a need for overcoming the disadvantages of the prior art as discussed above.

### SUMMARY OF THE INVENTION

The invention is targeted at solving these problems.

One aim of the invention is to form, at low temperature, thermodynamically stable tantalum pentoxide of good quality.

A further aim of the invention is the production of a layer of tantalum pentoxide that can be incorporated in an integrated circuit.

A further aim of the invention is to make possible the production of a more elastic dielectric that has better resistance to mechanical stresses.

One aim of the invention is to also make possible the production of a dielectric with a high nucleation quality.

The invention thus provides a process for the formation of a layer of tantalum pentoxide (Ta₂O₅) on a carrier material. According to a general characteristic of the invention, the carrier material is heated to a heating temperature of between 200° C. and 400° C. and a gas mixture comprising tert-butyliminotris (diethylamino) tantalum (t-BuN═Ta(NEt₂)₃) is circulated in contact with of the heated carrier material under an oxidizing atmosphere, the partial pressure of the tert-butyliminotris (diethylamino) tantalum being greater than or equal to 25 mTorr.

Thus, according to the invention, the combination

of the organometallic precursor TBTDET,

of a low temperature, preferably between 300° C. and 350° C., and

of a high TBTDET partial pressure,

makes it possible to obtain, at low temperature, tantalum pentoxide of good quality with regard to leakage currents. Thus, by way of indication, under the application of a voltage equal in absolute value to 3.6 volts approximately at the terminals of the dielectric, the leakage current, measured in amperes per cm² of surface area of dielectric, is less than 10^{-((x+20)/10)}, x being the tantalum pentoxide thickness measured in nanometers, this being the case for thicknesses ranging from 25 to 65 nanometers.

Control of the partial pressure of the TBTDET precursor makes it possible to control the rate of deposition and the quality of the nucleation.

Thus, when the TBTDET partial pressure is increased, the rate of deposition is then increased, which makes it possible to limit the duration of exposure of the carrier material in contact with the oxidizing medium, for example oxygen. This is particularly advantageous when the carrier material is titanium nitride but also when it is silicon. This is because, in the case of a carrier material made of titanium nitride, the decomposition of the interface between the titanium nitride and the tantalum pentoxide will be greatly reduced. In the case of a carrier material made of silicon, the silicon dioxide layer formed at the interface between the tantalum pentoxide and the silicon will be reduced.

Furthermore, the increase in the partial pressure of the organometallic precursor used, and consequently the increase in the rate of deposition, makes it possible to obtain a less dense and consequently more elastic dielectric material. This dielectric material will therefore have better resistance to the mechanical stresses that are produced, in particular during the cooling of the wafers of carrier material.

The increase in the partial pressure of the organometallic precursor makes it possible to increase the quality of the nucleation of the tantalum pentoxide on the carrier material, in particular on silicon and on titanium nitride. The advent of the three-dimensional growth of the tantalum pentoxide is therefore faster.

It has been observed that a value of 25 mtorr for this TBTDET partial pressure constituted an acceptable lower limit compatible with a satisfactory quality of the dielectric thus formed and with its incorporation in an integrated circuit.

Having said that, higher partial pressures make it possible to further improve the quality of the dielectric.

In this respect, although there exists no theoretical upper limit for the partial pressure of the organometallic precursor used, it is desirable, however, when the gas mixture is circulated in a chamber in which the carrier material is placed, for the partial pressure of the tert-butyliminotris (diethylamino) tantalum to be less than the vapor pressure of this tert-butyliminotris (diethylamino) tantalum corresponding to the temperature of the coldest point in the chamber.

This is because a person skilled in the art knows that the vapor pressure of a gas at a given temperature is the pressure beyond which the gas is converted to the liquid phase. Consequently, if the partial pressure of the TBTDET becomes greater than the vapor pressure of TBTDET corresponding to the temperature of the coldest point in the chamber, condensation will then begin to occur on the walls of the chamber. Although this does not put into question the advantages obtained by the invention, this condensation can be harmful in some applications and this is the reason why it is then preferable for the partial pressure of the TBTDET to be less than this vapor pressure corresponding to the coldest point in the chamber.

By way of indication, a TBTDET partial pressure of between 65 mTorr and 70 mTorr can be chosen. Furthermore, such a range is entirely compatible with a chamber with a cold point lying at 90° C., which then corresponds to a vapor pressure of the TBTDET equal to 75 mTorr.

The TBTDET can be mixed with any oxidizing atmosphere (O₂, O₃, H₂O or other). However, use will preferably be made of oxygen.

The gas mixture also advantageously comprises a carrier gas, for example nitrogen or argon.

The velocity of the gases, or the replacement time of the gases over the carrier material, makes it possible to refine the uniformity of the deposit of tantalum pentoxide. This replacement time can be adjusted according to the machine used and the application contemplated. Thus, when the gas mixture is circulated in a chamber in which the carrier material is placed, a replacement time of the gas mixture in the chamber of between 0.1 second and 10 minutes will be chosen, for example. Having said that, by way of indication, for the production of a uniform deposit of a few tens of nanometers, for example 44 nanometers, a replacement time of the order of 1 to 10 seconds and preferably of the order of 1 to 3 seconds can be chosen.

The choice of the carrier material is extremely broad.

Thus, the carrier material can be a semi-conducting material, for example a silicon substrate.

The carrier material can also be a metallic material, for example a material chosen from the group formed by titanium nitride (TiN), tantalum nitride (TaN), copper, platinum, aluminum, titanium, tantalum and ruthenium (Ru). Such metallic materials can thus form the metallic electrodes of a capacitor incorporated in an integrated circuit.

The carrier material can also be a dielectric material, for example a material chosen from the group formed by silicon dioxide, silicon nitride (Si₃N₄), alumina (Al₂O₃), ZrO₂ and HfO₂.

In practice, the thickness of the layer of tantalum pentoxide formed can be of the order of a few tens of nanometers, for example 44 nanometers.

Furthermore, the carrier material can in practice be positioned on a circular wafer having a diameter of approximately 200 mm or 300 mm.

The layer of tantalum pentoxide thus formed can be intended to be incorporated in one or more electronic integrated circuits.

Another subject matter of the invention is a device for the formation of a layer of tantalum pentoxide on a carrier material, comprising heating means capable of heating the carrier material and injection means capable of circulating a gas mixture in contact with the heated carrier material.

According to a general characteristic of the invention, the heating means is capable of heating the carrier material to a heating temperature of between 200° C. and 400° C. and the gas mixture comprises tert-butyliminotris (diethylamino) tantalum (t-BuN═Ta(NEt₂)₃) under an oxidizing atmosphere, the partial pressure of the tert-butyliminotris (diethylamino) tantalum being greater than or equal to 25 mTorr.

According to one embodiment of the invention, the device comprises a chamber in which the carrier material is placed and the partial pressure of the tert-butyliminotris (diethylamino) tantalum is less than the vapor pressure of tert-butyliminotris (diethylamino) tantalum corresponding to the temperature of the coldest point in the chamber.

The carrier material can be positioned on a circular wafer having, for example, a diameter of approximately 200 mm or 300 mm.

According to one embodiment of the invention, the chamber can comprise a single wafer or else several wafers.

Another subject matter of the invention is an integrated circuit comprising at least one capacitor comprising tantalum pentoxide positioned between two electrodes and obtained by the process as defined above.

According to an embodiment in which the tantalum pentoxide has a thickness x of between approximately 25 nanometers and 65 nanometers, the tantalum pentoxide exhibits, under a voltage difference applied between the two electrodes equal in absolute value to 3.6 volts approximately, a leakage current, measured in amperes per cm² of tantalum pentoxide surface area, of less than 10^{-((x+20)/10)}.

The electrodes of the capacitor can comprise titanium nitride in contact with the tantalum pentoxide.

The electrodes can also comprise a semi-conducting material, for example silicon.

The electrodes can also comprise a metallic material, for example a material taken from the group formed by tantalum nitride, copper, platinum, aluminum, titanium, tantalum and ruthenium.

### BRIEF DESCRIPTION OF THE DRAWING

Other advantages and characteristics of the invention will become apparent on examining the detailed description of embodiments, which are in no way limiting, and the appended drawings, in which:

FIG. 1 illustrates in a highly diagrammatic way a first embodiment of a device according to the invention that makes possible an implementation of the process according to the invention,

FIG. 2 illustrates in a highly diagrammatic and partial way a second embodiment of a device according to the invention,

FIG. 3 diagrammatically illustrates an integrated circuit according to the invention, and

FIG. 4 illustrates in a highly diagrammatic way a measurement of leakage current from a tantalum pentoxide layer obtained by the process according to the invention.

### DESCRIPTION OF THE PREFERRED EMBODIMENTS

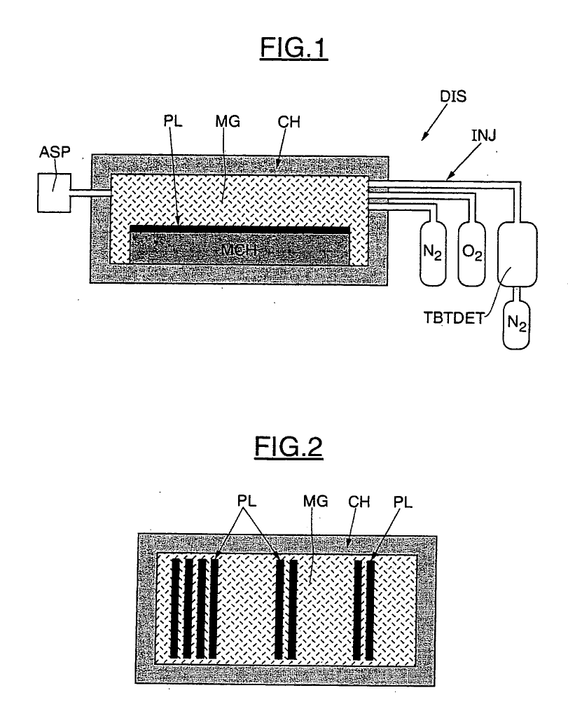

In FIG. 1, the reference DIS denotes a device intended to form a layer of tantalum pentoxide (Ta₂O₅) on the upper surface of a wafer PL formed of a carrier material, for example a wafer covered with titanium nitride (TiN).

This wafer is placed in a chamber CH and is heated by heating means MCH formed in this instance of a heating support.

Having said that, these heating means can be of any nature.

Injection means INJ, which can be formed of a means in the form of a shower head coming above the wafer PL or else formed of injection nozzles positioned on the walls of the chamber, make it possible to inject, into this chamber and in contact with the carrier material, a gas mixture MG comprising,

as organometallic precursor, TBTDET,

oxygen and

a carrier gas, for example nitrogen.

Suction means ASP make possible, in combination with the injection means, replacement of the gas mixture MG in the chamber.

Generally, the carrier material situated on the upper surface of the wafer is heated to a heating temperature of between 200° C. and 400° C. and the gas mixture MG is circulated in contact with the carrier material thus heated, the partial pressure of the TBTDET in the gas mixture being greater than or equal to 25 mTorr.

The TBTDET precursor will decompose and the BuN and NEt₂ groups will detach from the tantalum Ta to be discharged via the suction means ASP. The oxygen will then combine with the tantalum to form the tantalum pentoxide Ta₂O₅.

In the example described here, the replacement time of the gases is of the order of 1 to 3 seconds. Tests have been carried out at a heating temperature of 360° C. and 375° C. respectively.

For a temperature of 360° C., a uniform layer of Ta₂O₅ was obtained using a TBTDET partial pressure equal to 0.068 Torr, a partial pressure of the carrier gas (nitrogen) equal to 8.6 Torr and an oxygen partial pressure equal to 3.57 Torr.

For a heating temperature of 375° C., the TBTDET partial pressure can be lower, for example taken as equal to 0.04 Torr, while the nitrogen and oxygen partial pressures are equal to 6.45 Torr and 5.51 Torr respectively.

The two TBTDET partial pressures respectively used in the two examples described above remain below 75 mTorr, which corresponds to the vapor pressure of TBTDET for a temperature of 90° C., which constitutes the coldest point in the chamber used.

Under these conditions, condensation of the TBTDET on the walls of the chamber is avoided.

While, in the example illustrated in FIG. 1, the chamber comprises only a single wafer, which can be formed of a disc with a diameter of 200 mm or 300 mm, for example, it is possible to envisage using a chamber CH as illustrated in FIG. 2 in which several wafers PL, positioned vertically, can be brought into contact with the gas mixture MG.

The invention has many applications.

Mention may thus in particular be made of the structures of metal/dielectric/semiconductor capacitors (MIS structures) or else the structures of metal/dielectric/metal capacitors (MIM structures) for dynamic random access memory applications.

Mention may also be made of the MIS or MIM structures for analog or radio frequency capacitor applications or alternatively for deep trench capacitors.

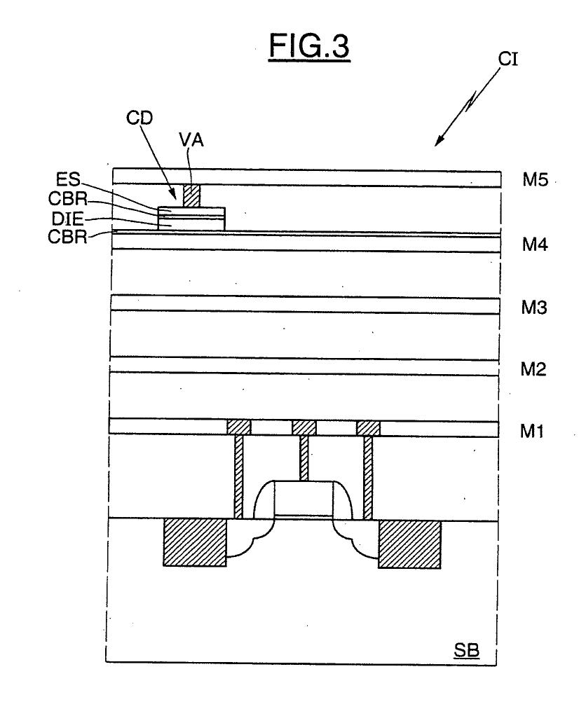

An example of an integrated circuit comprising a capacitor with a dielectric obtained by the process according to the invention is illustrated in FIG. 3.

This integrated circuit conventionally comprises active components, for example transistors, on a substrate SB. The integrated circuit also comprises several metallization levels M1-M5. Furthermore, a capacitor CD is produced between the 4-level metal M4 and the 5-level metal M5. The lower electrode of this capacitor CD is formed of a portion, covered with a barrier layer CBR made of titanium nitride, of the 4-level metal. The upper electrode ES is a metallic electrode, for example made of aluminum or of copper, also covered on its lower face with a barrier layer CBR made of titanium nitride. The dielectric DIE, formed of tantalum pentoxide, is positioned between the two layers of titanium nitride. The upper electrode ES is connected to the upper metallization level M5 by a via VA.

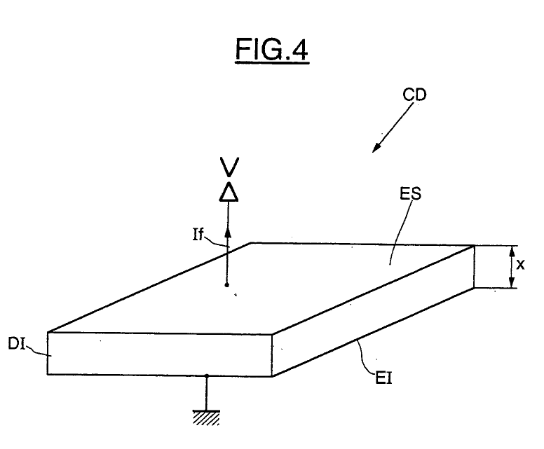

A layer of tantalum pentoxide obtained by the process according to the invention exhibits the distinguishing feature of being of very good quality with respect to leakage currents. More specifically, as illustrated in FIG. 4, if a voltage difference V equal in absolute value to 3.6 volts approximately is applied between the two electrodes ES and EI of a capacitor CD, the dielectric DI of which is formed of tantalum pentoxide obtained by the process according to the invention, a leakage current if of less than 10^{-((x+20)/10)}, where x denotes the thickness of the dielectric layer expressed in nanometers, will be observed. Furthermore, in this formula, the current If is expressed in amperes per square centimeter of tantalum pentoxide surface area.

The present invention is not limited to the examples described above. Many alternative embodiments are possible without departing from the scope defined by the appended claims. For example, it should be obvious to those of ordinary skill in the art in view of the present discussion that alternative embodiments of the new and novel memory circuit may be implemented in an integrated circuit comprising a circuit supporting substrate that supports at least a portion of the new and novel memory circuit discussed above. Additionally, the new and novel integrated circuit may be implemented in a computer system comprising at least one integrated circuit thereby providing the advantages of the present invention to such computer system.

While there has been illustrated and described what are presently considered to be the preferred embodiments of the present invention, it will be understood by those of ordinary skill in the art that various other modifications may be made, and equivalents may be substituted, without departing from the true scope of the present invention.

Additionally, many modifications may be made to adapt a particular situation to the teachings of the present invention without departing from the central inventive concept described herein. Furthermore, an embodiment of the present invention may not include all of the features described above. Therefore, it is intended that the present invention not be limited to the particular embodiments disclosed, but that the invention include all embodiments falling within the scope of the appended claims.

What is claimed is:

1. A process for formation of a layer of tantalum pentoxide (Ta₂O₅) on a carrier material, comprising:
heating carrier material to a heating temperature of between approximately 200° C. and 400° C.; and
circulating a gas mixture comprising tert-butyliminotris (diethylamino) tantalum (t-BuN═Ta(NEt₂)₃) in contact with the heated carrier material under an oxidizing atmosphere thereby forming a layer of tantalum pentoxide (Ta₂O₅) on the carrier material, the partial pressure of the tert-butyliminotris (diethylamino) tantalum being greater than or equal to 25 mTorr.

2. The process according to claim 1, wherein the heating temperature is between approximately 300° C. and 350° C.

3. The process according to claim 1, wherein the gas mixture is circulated in a chamber in which the carrier material is placed and in that the partial pressure of the tert-butyliminotris (diethylamino) tantalum is less than the vapor pressure of tert-butyliminotris (diethylamino) tantalum corresponding to the temperature of the coldest point in the chamber.

4. The process according to claim 1, wherein the partial pressure of the tert-butyimiotris (diethylmino) tantalum is between approximately 65 mTorr and 70 mTorr.

5. The process according to claim 1, wherein the gas mixture comprises oxygen.

6. The process according to claim 1, wherein the gas mixture comprises a carrier gas, for example nitrogen.

7. The process according to claim 1, wherein the gas mixture is circulated in a chamber in which the carrier material is placed and in that the replacement time of the gas mixture in the chamber is between 0.1 second and 10 minutes, for example of the order of 1 to 10 seconds.

8. The process according to claim 1, wherein the carrier material is a semi-conducting material, for example silicon.

9. The process according to claim 1, wherein the carrier material is a metallic material.

10. The process according to claim 9, wherein the metallic material is chosen from the group formed by titanium nitride, tantalum nitride, copper, platinum, aluminum, titanium, tantalum and ruthenium.

11. The process according to claim 1, wherein the carrier material is a dielectric material.

12. The process according to claim 11, wherein the dielectric material is chosen from the group formed by silicon dioxide (SiO₂), silicon nitride (Si₃N₄), alumina (Al₂O), ZrO₂ and HfO₂.

13. The process according to claim 1, wherein the thickness of the layer of tantalum pentoxide formed is of the order of a few tens of nanometers, for example 44 nanometers.

14. The process according to claim 1, wherein the carrier material is positioned on a circular wafer having a diameter of substantially one of 200 mm and 300 mm.

15. The process according to claim 1, wherein the layer of tantalum pentoxide is for incorporating in one or more electronic integrated circuits.

16. A device for the formation of a layer of tantalum pentoxide (Ta₂O₅) on a carrier material, comprising:
heating means for heating carrier material;
injection means for circulating a gas mixture in contact with the heated carrier material thereby forming a layer of tantalum pentoxide (Ta₂O₅) on the carrier material, wherein the heating means is for heating the carrier material to a heating temperature of between approximately 200° C. and 400° C., and in that the gas mixture comprises tert-butyliminotris (diethylamino) tantalum (t-BuN═Ta(NEt₂)₃) under an oxidizing atmosphere, the partial pressure of the tert-butyliminotris (diethylamino) tantalum being greater than or equal to 25 mTorr.

17. The device according to claim 16, wherein the heating temperature is between approximately 300° C. and 350° C.

18. The device according to claim 16, further comprising a chamber in which the carrier material is placed and in that the partial pressure of the tert-butyliminotris (diethylamino) tantalum is less than the vapor pressure of tert-butyliminotris (diethylamino) tantalum corresponding to the temperature of the coldest point in the chamber.

19. The device according to claim 16, wherein the partial pressure of the tert-butyliminotris (diethylamino) tantalum is between approximately 65 mTorr and 70 mTorr.

20. The device according to claim 16, wherein the gas mixture comprises oxygen.

21. The device according to claim 16, wherein the gas mixture comprises a carrier gas, for example nitrogen.

22. The device according to claim 16, further comprising a chamber in which the carrier material is placed and in which the gas mixture circulates and in that the replacement time of the gas mixture in the chamber is between 0.1 second and 10 minutes, for example of the order of 1 to 10 seconds.

23. The device according to claim 16, wherein the carrier material is a semi-conducting material, for example silicon.

24. The device according to claim 16, wherein the carrier material is a metallic material.

25. The device according to claim 24, wherein the metallic material is chosen from the group formed by titanium nitride, tantalum nitride, copper, platinum, aluminum, titanium, tantalum and ruthenium.

26. The device according to claim 16, wherein the carrier material is a dielectric material.

27. The device according to claim 26, wherein the dielectric material is chosen from the group formed by silicon dioxide (SiO₂), silicon nitride (Si₃N₄), alumina (Al₂O₃), ZrO₂ and HfO₂.

28. The device according to claim 16, wherein the thickness of the layer of tantalum pentoxide formed is of the order of a few tens of nanometers, for example 44 nanometers.

29. The device according to claim 16, wherein the carrier material is positioned on a circular wafer having a diameter of substantially one of 200 mm and 300 mm.

30. The device according to claim 29, wherein the chamber comprises a single wafer.

31. The device according to claim 29, wherein the chamber comprises several wafers.

32. The device according to claim 16, wherein the layer of tantalum pentoxide is for incorporating in one or more electronic integrated circuits.

33. An integrated circuit, comprising:
at least one capacitor comprising tantalum pentoxide positioned between two electrodes, the at least one capacitor being obtained by a process comprising:
heating carrier material to a heating temperature of between approximately 200° C. and 400° C.; and
circulating a gas mixture comprising tert-butyliminotris (diethylamino) tantalum (t-BuN═Ta(NEt₂)₃) in contact with the heated carrier material under an oxidizing atmosphere thereby forming a layer of tantalum pentoxide on the carrier material, the partial pressure of the tert-butyliminotris (diethylamino) tantalum being greater than or equal to 25 mtorr.

34. The integrated circuit according to claim 33, wherein the tantalum pentoxide has a thickness of between approximately 25 nanometers and 65 nanometers and exhibits, under a voltage difference applied between the two electrodes equal in absolute value to 3.6 volts approximately, a leakage current, measured in amperes per cm² of tantalum pentoxide surface area, of approximately less than 10^{-((x+20)/10)}.

35. The integrated circuit according to claim 33, wherein the electrodes comprise titanium nitride in contact with the tantalum pentoxide.

36. The integrated circuit according to claim 33, wherein the electrodes comprise a semi-conducting material, for example silicon.

37. The integrated circuit according to claim 33, wherein the electrodes comprise a metallic material.

38. The integrated circuit according to claim 37, wherein the electrodes comprise a material taken from the group formed by tantalum nitride, copper, platinum, aluminum, titanium, tantalum and ruthenium.

39. The integrated circuit according to claim 33, wherein the thickness of the layer of tantalum pentoxide formed is approximately equal to 44 nanometers.
